(19) United States
(12) Patent Application Publication
(10) Pub. No.: US 2002/0179988 A1
(43) Pub. Date: Dec. 5, 2002

(54) Pakage structure integrating image sensor to controller chip of scanning apparatus

(76) Inventor: Sean Chiu, Taipei (TW)

Correspondence Address: RABIN & CHAMPAGNE, PC, 1101 14TH STREET, NW, SUITE 500, WASHINGTON, DC, 20005, US

(21) Appl. No.: 09/871,622

(22) Filed: Jun. 4, 2001

(51) Int. Cl. H01L 31/0203

(52) U.S. Cl. 257/434; 257/433; 257/680; 257/723

(57) ABSTRACT

A package structure integrating image sensor to controller chip of scanning apparatus comprises an unpackaged controller chip having a plurality of bonding pads; an image sensor mounted atop the controller chip and connected to the bonding pads of the controller chip; a protective cover provided to cover a connection portion of the controller chip and the image sensor; and a transparent window placed atop the protective cover. The image sensor receives light passing through the transparent window and generates a corresponding electronic signal, which is sent to the controller chip for further process. The assembling cost of the scanner is reduced. The EMI is reduced and the signal distortion due to conductive wiring is also reduced.

### FIELD OF THE INVENTION

The present invention relates to a package structure integrating an image sensor to a controller chip of scanning apparatus, especially to a package structure integrating an image sensor to a controller chip of scanner.

### BACKGROUND OF THE INVENTION

As the population of scanner, the scanner is demanded to have lower price, higher speed, higher resolution and more function.

Moreover, the current trend for computer product is to integrating more electronic components together due to the progress of fabrication technology. The scanner generally comprises at least an image sensor, a motor driving mechanism, an illuminating lamp and a controller chip on circuit board of the scanner. The controller chip 60 on the circuit board 50 of the scanner integrates nearly all functions on the circuit board 50 of the scanner. As shown in FIG. 1, the pins of the controller chip 60 on the circuit board 50 are electrically connected to the image sensor 70 through a plurality of conductive wires 80.

However, the frequently used CCD sensor for the image sensor 70 has fabrication process not compatible with the CMOS process of the controller chip 60. Moreover, the CCD sensor has different structure with the controller chip 60. The image sensor 70 is hard to be integrated with the controller chip 60. Moreover, the conductive wires 80 are not immune to EMI (electromagnetic interference), the performance of the controller chip 60 is degraded.

### SUMMARY OF THE INVENTION

It is the object of the present invention to provide a package structure integrating an image sensor to a controller chip of scanning apparatus.

In one aspect of the invention, the image sensor mounted atop the unpackaged controller chip and connected to the bonding pads of the controller chip. A protective cover is provided to cover a connection portion of the controller chip and the image sensor. A transparent window is placed atop the protective cover. The image sensor receives light passing through the transparent window and generates a corresponding electronic signal, which is sent to the controller chip for further process.

In another aspect of the invention, the present invention provides a package structure integrating an image sensor to a controller chip of scanning apparatus, wherein the circuit board of scanner has not independently packaged image sensor, the complexity of the circuit board of scanner is reduced. The EMI is reduced and the signal distortion due to conductive wiring is also reduced.

In another aspect of the invention, the present invention provides a package structure integrating an image sensor to a controller chip of scanning apparatus, wherein the signal input ways, exposure time, signal compensation and calibration, and signal process have more flexibility.

The various objects and advantages of the present invention will be more readily understood from the following detailed description when read in conjunction with the appended drawing, in which:

### BRIEF DESCRIPTION OF DRAWING

FIG. 1 shows the perspective view of prior art packaged controller chip arranged on a circuit board with an image sensor;

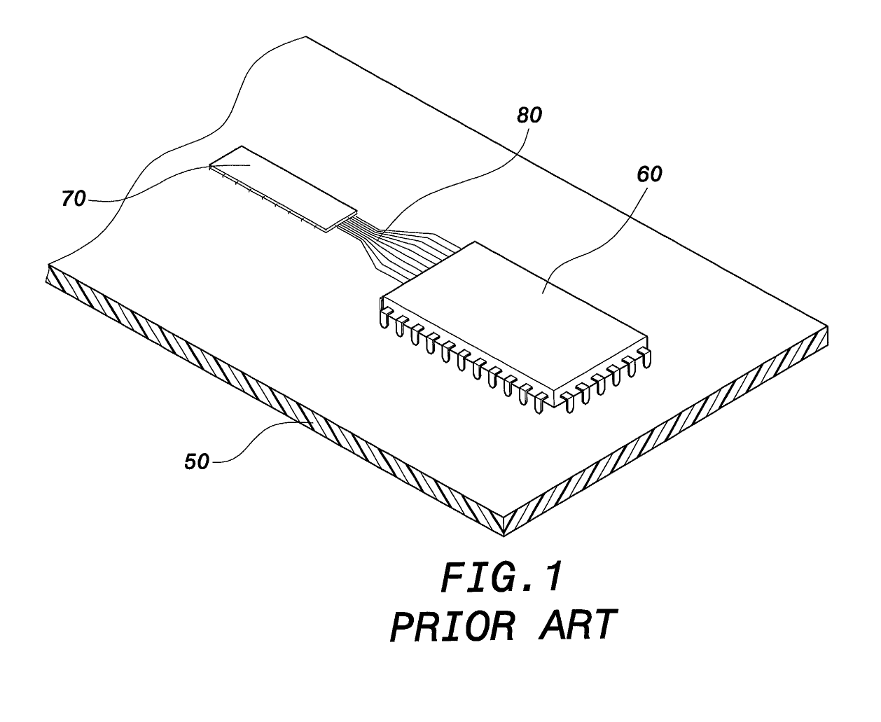

FIG. 2 shows the perspective view of the present invention;

FIG. 3 shows the package of the present invention applied to a scanner;

FIG. 4 shows the segmentation of the image sensor in the present invention;

FIG. 5 shows the sectional view of one detection unit;

FIG. 6 shows another preferred embodiment of the present invention.

### DESCRIPTION OF THE INVENTION

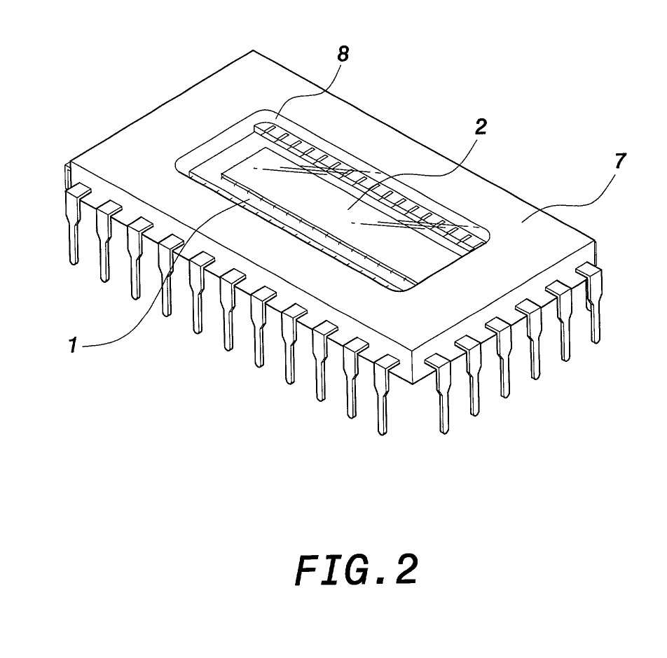

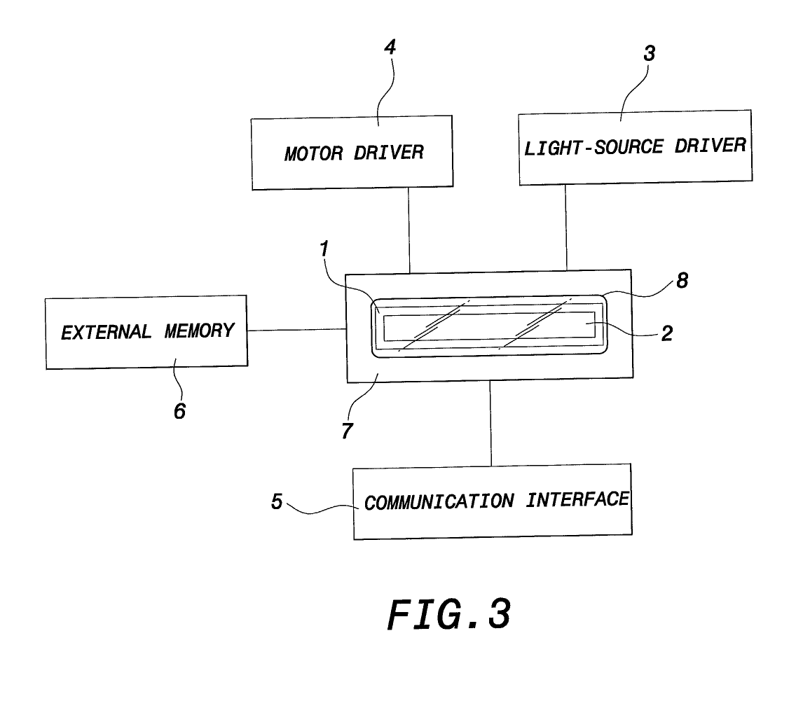

FIGS. 2 and 3 show the package structure integrating an image sensor to a controller chip of scanning apparatus according to the present invention. The package structure according to the present invention is used to package an unpackaged controller chip 1 and an image sensor 2.

The controller chip 1 is arranged on a circuit board (not shown) of a scanning apparatus and is connected to a light-source driver 3, a motor driver 4, a communication interface 5, and an external memory 6. In the preferred embodiment of the invention, the scanning apparatus is a scanner.

The image sensor 2 is mounted atop the controller chip 1 and is connected to the bonding pads of the controller chip 1. A protective cover 7 is provided to cover the connection portion of the controller chip 1 and the image sensor 2; and a transparent window 8 is placed atop the protective cover 7. The image sensor 2 receives light passing through the transparent window 8 and generates a corresponding electronic signal. The electronic signal is sent to the controller chip 1 for further process.

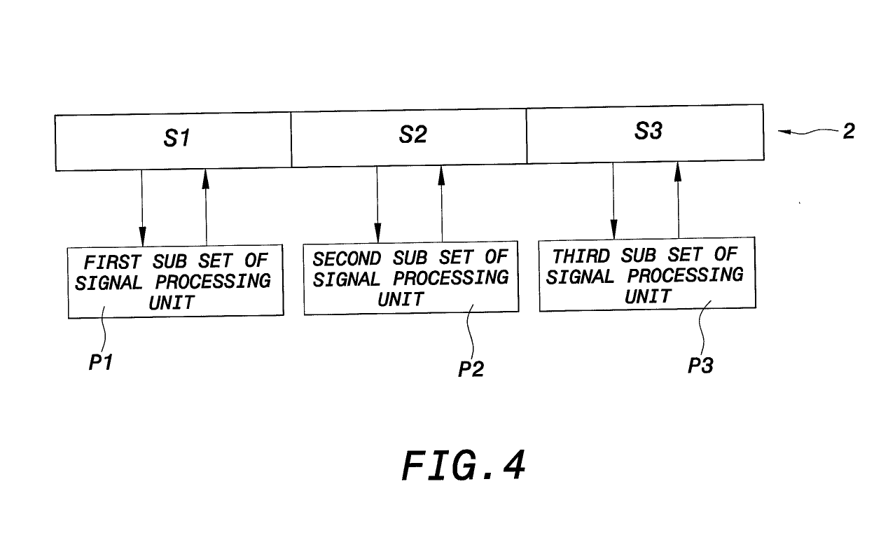

As shown in FIG. 4, the image sensor 2 on the controller chip 1 is composed of a plurality of detection units and segmented to a plurality of sub sets, for example, three sub sets S1-S3, and the signal detection and output are independently carried out for each sub set. The controller chip 1 also have a plurality of corresponding processing units, for example, three processing units P1-P3 to parallel process the three sub sets S1-S3 of the image sensor 2. The processing speed can be enhanced to improve performance of the scanner.

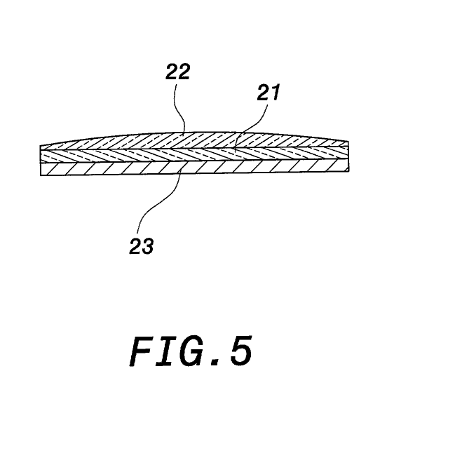

Moreover, the image sensor 2 of the present invention can comprise a plurality of sub sets of detection units in linear arrangement. FIG. 5 shows the sectional view of one detection unit 23, wherein a color filter 21 and a micro-lens 22 are fabricated thereon by micro-fabrication process.

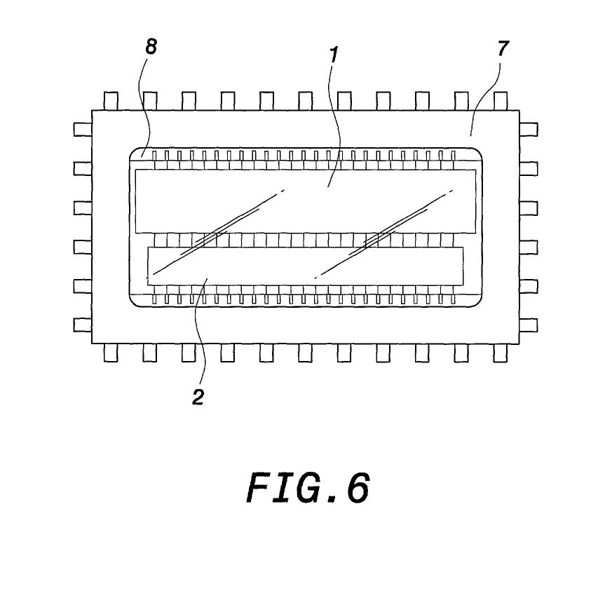

FIG. 6 shows another preferred embodiment of the present invention. The image sensor 2 is arranged on one side of an unpackaged controller chip I and is connected to the bonding pads of the controller chip 1. Moreover, a protective cover 7 is provided to cover the connection portion of the controller chip 1 and the image sensor 2.

To sum up, the package structure according to the present invention has following advantages:

(1) The assembling cost of the scanner is reduced.

(2) The circuit board of scanner has not independently packaged image sensor, the complexity of the circuit board of scanner is reduced. The EMI is reduced and the signal distortion due to conductive wiring is also reduced.

(3) The signal input ways, exposure time, signal compensation and calibration, and signal process have more flexibility.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. A package structure integrating image sensor to controller chip of scanning apparatus, comprising:
an unpackaged controller chip having a plurality of bonding pads;
an image sensor mounted atop the controller chip and connected to the bonding pads of the controller chip; a protective cover provided to cover a connection portion of the controller chip and the image sensor; and
a transparent window placed atop the protective cover;
wherein the image sensor receiving light passing through the transparent window and generating a corresponding electronic signal, which is sent to the controller chip for further process.

2. The package structure integrating image sensor to controller chip of scanning apparatus as in claim 1, wherein the image sensor is segmented into a plurality of sub sets, each sub set having independent sensing operation and signal output, whereby the controller chip can execute parallel processing for each sub set.

3. The package structure integrating image sensor to controller chip of scanning apparatus as in claim 1, wherein the image sensor is composed of a plurality of sub sets of detection units.

4. The package structure integrating image sensor to controller chip of scanning apparatus as in claim 3, wherein the detection unit has a color filter and a micro-lens.

5. The package structure integrating image sensor to controller chip of scanning apparatus as in claim 1, wherein the image sensor is arranged on surface of the unpackaged controller chip.

6. The package structure integrating image sensor to controller chip of scanning apparatus as in claim 1, wherein the image sensor is arranged on one lateral side of the unpackaged controller chip.

7. The package structure integrating image sensor to controller chip of scanning apparatus as in claim 1, wherein the image sensor can be integrated into a single chip with the unpackaged controller chip.
